(19) United States
(12) Patent Application Publication
(10) Pub. No.: US 2024/0188308 A1
(43) Pub. Date: Jun. 6, 2024

(54) MEMORY CELL PROTECTIVE LAYERS IN A THREE-DIMENSIONAL MEMORY ARRAY

(71) Applicant: Micron Technology, Inc., Boise, ID (US)

(72) Inventor: Farrell M. Good, Meridian, ID (US)

(21) Appl. No.: 18/520,377

(22) Filed: Nov. 27, 2023

Related U.S. Application Data
(60) Provisional application No. 63/430,272, filed on Dec. 5, 2022.

(51) Int. Cl. H10B 63/00

(52) U.S. Cl. CPC H10B 63/845

(57) ABSTRACT

Methods, systems, and devices for memory cell protective layers in a three-dimensional memory array are described. A memory device may support accessing memory cells of a memory array arranged in a three-dimensional architecture. The three-dimensional architecture may include levels of memory cells separated by levels of dielectric materials, such that the memory cells are formed between the dielectric materials. To prevent or reduce diffusion between a given memory cell and the dielectric materials, a barrier material may be formed on the dielectric material before forming the memory cell. The barrier material may be located between the memory cell and dielectric material, which may reduce or prevent material diffusion.

### CROSS REFERENCE

The present application for patent claims priority to U.S. Patent Application No. 63/430,272 by Good, entitled “MEMORY CELL PROTECTIVE LAYERS IN A THREE-DIMENSIONAL MEMORY ARRAY,” filed Dec. 5, 2022, which is assigned to the assignee hereof, and which is expressly incorporated by reference herein.

### TECHNICAL FIELD

The following relates to one or more systems for memory, including memory cell protective layers in a three-dimensional memory array.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, a component may read (e.g., sense, detect, retrieve, identify, determine, evaluate) a stored state in the memory device. To store information, a component may write (e.g., program, set, assign) the state in the memory device.

Various types of memory devices and memory cells exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a memory device that supports memory cell protective layers in a three-dimensional memory array in accordance with examples as disclosed herein.

FIG. 2 illustrates a top view of an example of a memory array that supports memory cell protective layers in a three-dimensional memory array in accordance with examples as disclosed herein.

FIGS. 3A and 3B illustrate side views of an example of a memory array that supports memory cell protective layers in a three-dimensional memory array in accordance with examples as disclosed herein.

FIGS. 4A, 4B, and 4C illustrates an example of operations of a manufacturing process that supports memory cell protective layers in a three-dimensional memory array in accordance with examples as disclosed herein.

FIG. 5 illustrates an example of operations of a manufacturing process that supports memory cell protective layers in a three-dimensional memory array in accordance with examples as disclosed herein.

FIGS. 6 and 7 illustrate flowcharts showing a method or methods that support memory cell protective layers in a three-dimensional memory array in accordance with examples as disclosed herein.

### DETAILED DESCRIPTION

In some memory architectures, a memory device may include a memory array arranged in a three-dimensional architecture that includes memory cells arranged according to different levels (e.g., layers, decks, planes, tiers). In some such architectures, levels of memory cells may be separated by layers of dielectric materials, and the memory cells may be formed in contact with respective layers of the dielectric materials (e.g., layers of the dielectric materials above and below the memory cells). In some cases, however, when a given memory cell is accessed, the memory cell may experience an increase in temperature, which may contribute to a diffusion of materials between the respective memory cell and the dielectric material (e.g., diffusion of selenium out of the memory cell, diffusion of oxygen into the memory cell, and the like) occurring. Additionally or alternatively, the memory cell may experience an increase in temperature as a result of thermal fabrication, material fabrication, processes, assembly processes, testing operations, and/or electrical heating during cell operation, each of which may cause the diffusion of materials. The diffusion of materials may change the material properties of the memory cell and negatively impact overall performance. For example, changes in material properties of a memory cell may affect how the memory cell reacts to various voltage biases applied across the memory cell, which may reduce a reliability of accessing the memory cell, among other issues.

In accordance with examples described herein, a barrier material may be used to reduce or eliminate diffusion between memory cells and dielectric materials. For example, before forming the memory cell, a manufacturing process may include forming a barrier material that includes boron (e.g., boron nitride, silicon boron nitride, among other materials that include boron) on portions of respective dielectric material layers between which the memory cell is formed. The memory cell may be formed between the barrier material on the respective dielectric material layers. That is, the barrier material may be located between the memory cell and dielectric material, thereby preventing or reducing diffusion between the memory cell and dielectric material while supporting access operations for the memory cell.

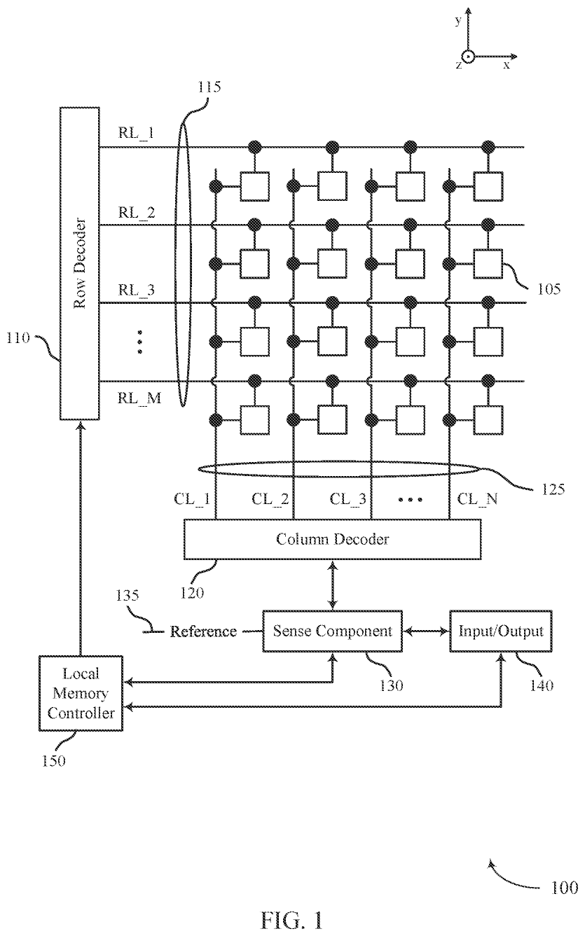

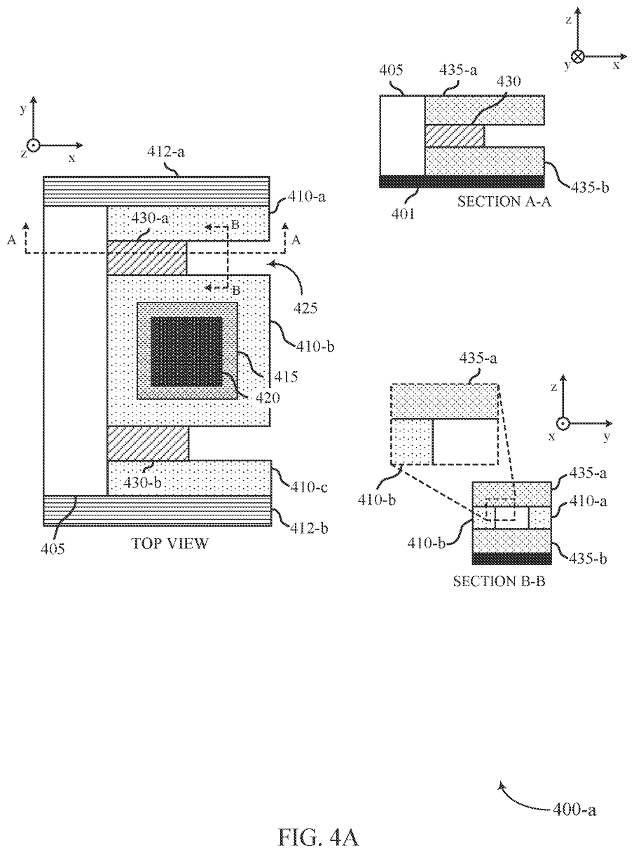

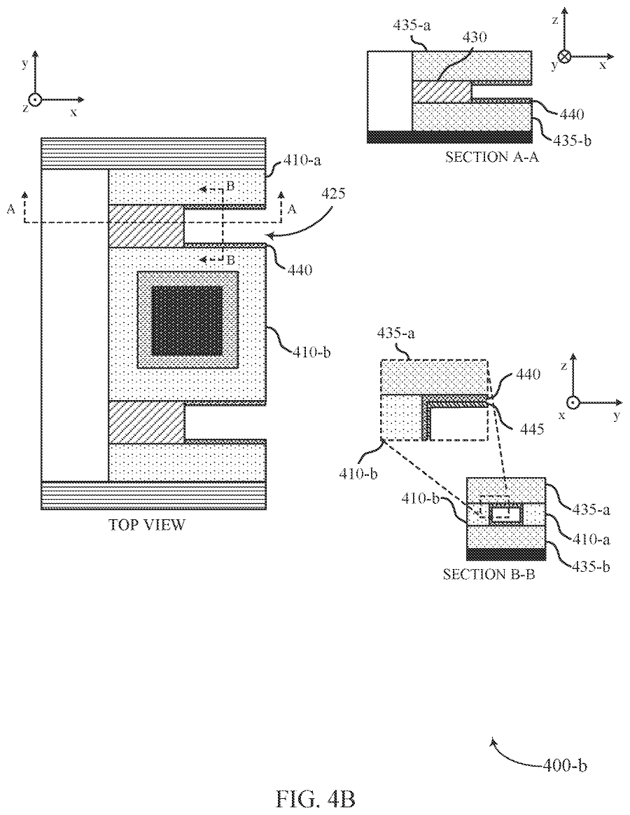

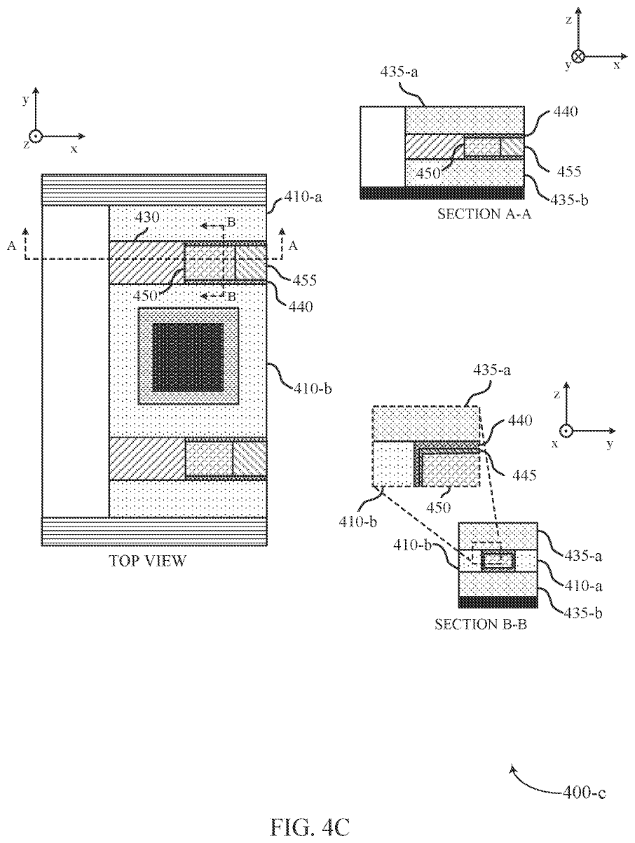

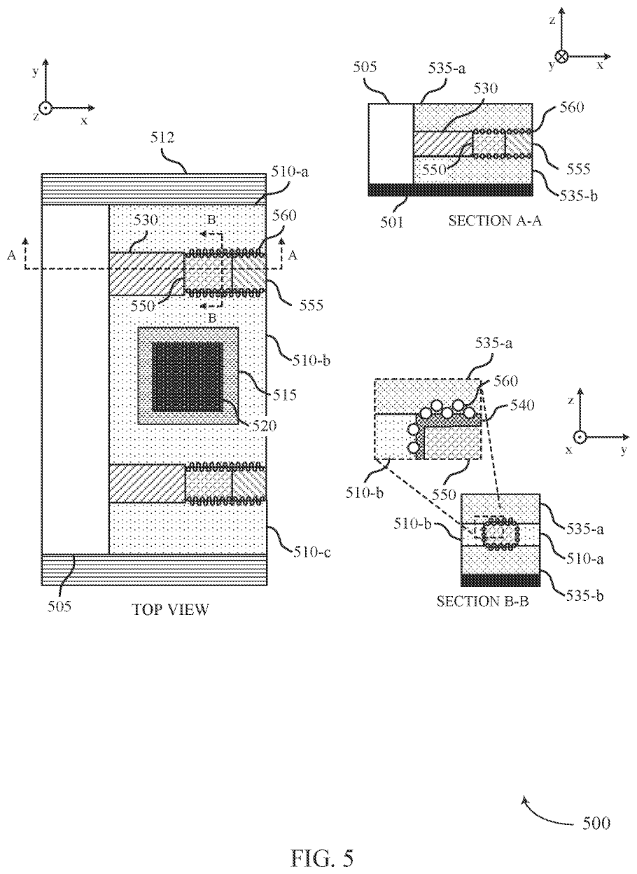

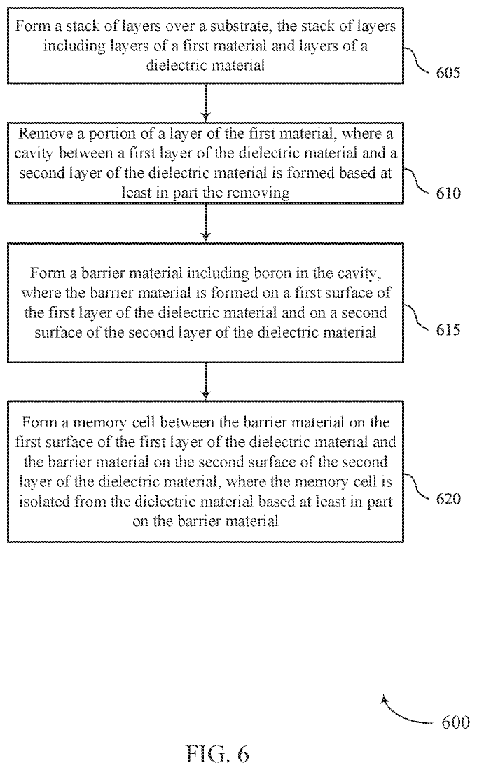

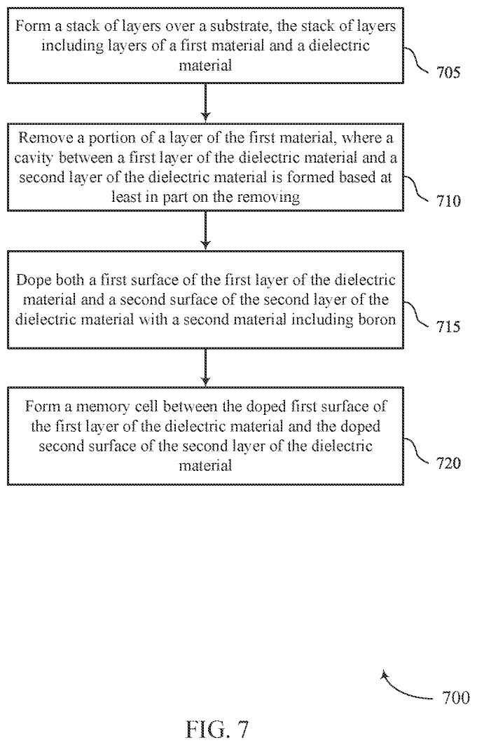

Features of the disclosure are initially described in the context of memory devices and arrays with reference to FIGS. 1, 2, 3A, and 3B. Features of the disclosure are described in the context of manufacturing operations with reference to FIGS. 4A, 4B, 4C, and 5. These and other features of the disclosure are further illustrated by and described with reference to an apparatus diagram and flowcharts that relate to memory cell protective layers in a three-dimensional memory array as described with reference to FIGS. 6 and 7.

FIG. 1 illustrates an example of a memory device 100 that supports memory cell protective layers in a three-dimensional memory array in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (in) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1). In some examples, a memory cell 105 may be operated so as to change logic states without physical phase changes. For example, a memory cell 105 may implement a threshold switching mechanism in which the logic state may change via positive and negative programming signals.

In some examples, (e.g., for thresholding memory cells 105, for self-selecting memory cells 105), some or all of the set of logic states supported by the memory cells 105 may be associated with morphological changes induced through operation of the memory cell (e.g., structural changes in bonding coordination). For example, some or all of the set of logical states may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

In some examples, a memory device 100 may include an array of memory cells 105 arranged in a three-dimensional architecture that includes memory cells 105 arranged according to different levels (e.g., layers, decks, tiers). For example, levels of memory cells 105 may be separated by levels of dielectric materials such that the memory cells 105 are formed in contact with the dielectric materials. However, in some cases, when a given memory cell 105 is accessed, the memory cell 105 may experience an increase in temperature, and a diffusion of materials between the respective memory cell 105 and the dielectric material may occur as a result of the increase in temperature (e.g., and a direct contact between the memory cell 105 and the dielectric material). Additionally or alternatively, the memory cell 105 may experience an increase in temperature as a result of thermal fabrication, material fabrication, processes, assembly processes, testing operations, and/or electrical heating during cell operation, each of which may cause the diffusion of materials. In some cases, the diffusion of materials may change the material properties of the memory cell 105 and negatively impact overall performance.

To prevent or reduce diffusion between the memory cell 105 and dielectric material, while supporting access operations for the memory cell 105, a barrier material may be used to isolate memory cells 105 from the dielectric materials. For example, before forming the memory cell 105, a manufacturing process may include forming a barrier material that includes boron (e.g., boron nitride, silicon boron nitride, among other materials that include boron) on the dielectric material. The memory cell 105 may be formed such that the barrier material may be located between the memory cell 105 and dielectric material, reducing or eliminating contact between the memory cell 105 and the dielectric material. The barrier material may be a material for which material diffusion between the memory cell 105 and the barrier material does not occur. The barrier material may also be a material that reduces or prevents oxygen diffusion into the memory cell (e.g., due to an attraction between boron and oxygen materials). Thus, the barrier material may support reduced or eliminated diffusion between the memory cell 105 and the dielectric material.

The memory device 100 may include any quantity of non-transitory computer readable media that support memory cell protective layers in a three-dimensional memory array. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

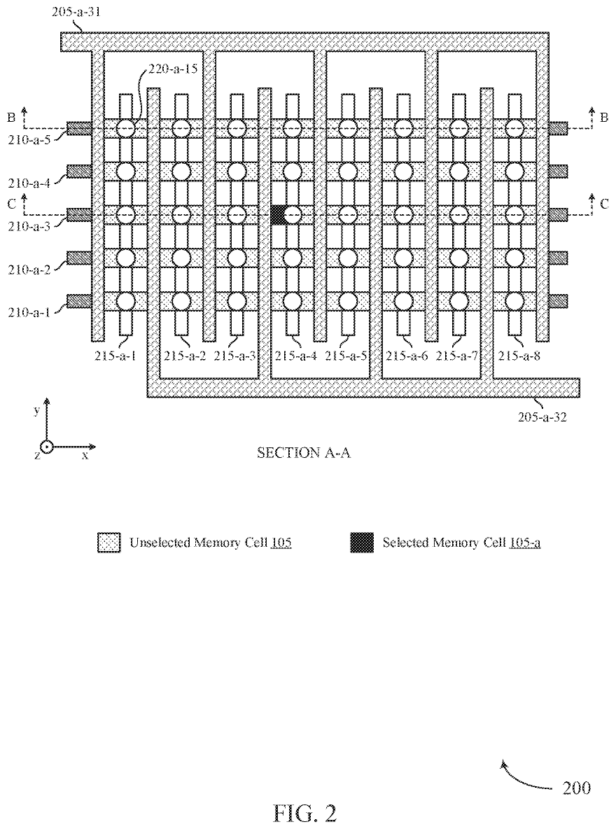

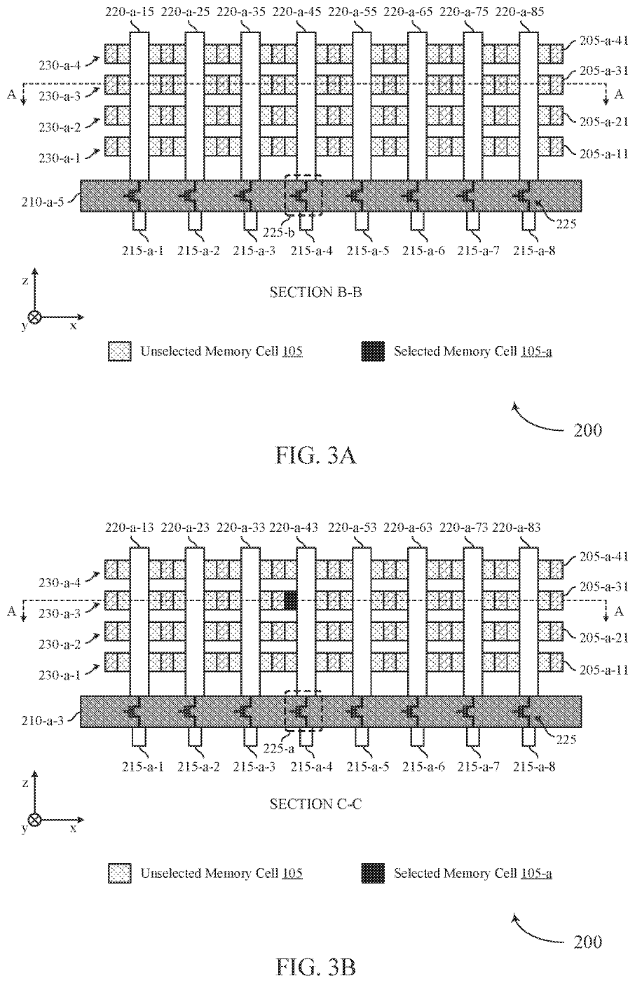

FIGS. 2, 3A, and 3B illustrate an example of a memory array 200 that supports memory cell protective layers in a three-dimensional memory array in accordance with examples as disclosed herein. The memory array 200 may be included in a memory device 100, and illustrates an example of a three-dimensional arrangement of memory cells 105 that may be accessed by various conductive structures (e.g., access lines). FIG. 2 illustrates a top section view (e.g., SECTION A-A) of the memory array 200 relative to a cut plane A-A as shown in FIGS. 3A and 3B. FIG. 3A illustrates a side section view (e.g., SECTION B-B) of the memory array 200 relative to a cut plane B-B as shown in FIG. 2. FIG. 3B illustrates a side section view (e.g., SECTION C-C) of the memory array 200 relative to a cut plane C-C as shown in FIG. 2. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 3A and 3B). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 3A, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In some examples, the levels 230 of memory cells 105 may be separated by levels of dielectric materials such that the memory cells 105 are formed in contact with the dielectric materials. However, in some cases, when a given memory cell 105 is accessed, the memory cell 105 may experience an increase in temperature, and a diffusion of materials between the respective memory cell 105 and the dielectric material may occur as a result. In some cases, the diffusion of materials may change the material properties of the memory cell 105 and negatively impact overall performance.

To prevent or reduce diffusion between the memory cell 105 and dielectric material, while supporting access operations for the memory cell 105, a barrier material may be used to isolate memory cells 105 from the dielectric materials. For example, before forming the memory cell 105, a manufacturing process may include forming a barrier material that includes boron on the dielectric material. The memory cell 105 may subsequently be formed such that the barrier material may be located between the memory cell 105 and dielectric material, which may prevent or reduce diffusion between the memory cell 105 and the dielectric material.

FIGS. 4 through 5 illustrate examples of operations that support memory cell protective layers in a three-dimensional memory array in accordance with examples as disclosed herein. For example, FIGS. 4A, 4B, and 4C may illustrate aspects of a sequence of operations for fabricating aspects of a layout 400, which may be a portion of a memory device (e.g., a portion of a memory device 100, a portion of a memory array 200, a portion of a memory die, a layout 400), and FIG. 5 may similarly illustrate aspects of a sequence of operations for fabricating aspects of a layout 500, which may be a portion of a memory device. Each view of the figures may be described with reference to an x-direction, a y-direction, and a z-direction, as illustrated, which may correspond to the respective directions described with reference to the memory array 200. Some of the provided figures include section views that illustrate example cross-sections of the layout 400 and 500, respectively. For example, in FIGS. 4A, 4B, 4C, and 5 a view “SECTION A-A” may be associated with a cross-section in an xz-plane (e.g., in accordance with a cut plane A-A) through a portion of the layout 400, and a view “SECTION B-B” may be associated with a cross-section in an yz-plane (e.g., in accordance with a cut plane B-B) through a portion of the layout 400. Although the layouts 400 and 500 illustrates examples of certain relative dimensions and quantities of various features, aspects of the layouts 400 and 500 may be implemented with other relative dimensions or quantities of such features in accordance with examples as disclosed herein.

Operations illustrated in and described with reference to FIGS. 4 through 5 may be performed by a manufacturing system, such as a semiconductor fabrication system configured to perform additive operations such as deposition, doping, or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 4A illustrates a portion 400-a of the layout 400 after a first set of one or more manufacturing operations that supports memory cell protective layers in a three-dimensional memory array in accordance with examples as disclosed herein.

The first set of manufacturing operations may include forming (e.g., depositing) a stack of layers over a substrate 401. The substrate 401 may be a semiconductor wafer or other substrate over which the stack of layers is deposited. The stack of layers may include alternating layers of a first material and a dielectric material 435 (e.g., in accordance with alternating material deposition operations). In some examples, the first material may be a dielectric material, such as a nitride (e.g., silicon nitride or another tier nitride), and the layers of the first material may be sacrificial layers. That is, the first material may be subsequently removed (e.g., exhumed, etched) and replaced with one or more other materials that form aspects of the memory device. The dielectric material 435 may include a dielectric material such as an oxide (e.g., silicon dioxide or another tier oxide), and may provide electrical isolation between levels 230. Although the stack of layers is illustrated with two layers of the dielectric material 435, a stack of layers in accordance with examples as disclosed herein may include any quantity of alternating layers of first material and the dielectric material 435 (e.g., tens of layers, hundreds of layers, and so on).

In some cases, the stack of layers may be deposited in direct contact with the substrate 401, and in some other examples, the layout 400 may include other materials or components between the stack of layers and the substrate 401, such as interconnection or routing circuitry (e.g., access lines, sense lines 215, gate lines 210), control circuitry (e.g., transistors 225, aspects of a local memory controller 150, decoders, multiplexers, and the like), or another stack of layers (e.g., another stack of layers processed in accordance with examples as disclosed herein), which may include various conductor, semiconductor, or dielectric materials between the stack of layers and the substrate 401. In some examples, the substrate 401 itself may include such interconnection or routing circuitry (e.g., based on doping various portions of the substrate 401). In some cases, the stack of layers may be deposited in a memory region of the memory device (e.g., a region of the memory device in which memory cells 105 are located). Additionally, the top view of FIG. 4A may illustrate a view of the layout 400 at a given level (e.g., level 230).

The first set of manufacturing operations may also include operations (e.g., a pillar etch operation, a pier etch operation) that support forming pillars, piers, or both, in accordance with examples as disclosed herein. For example, the first set of manufacturing operations may include forming one or more cavities through the stack of layers (e.g., by removing portions of the first material and the dielectric material 435 along the z-direction to the substrate 401 or to an intervening material between the stack of layers and the substrate 401).

The first set of manufacturing operations may include further operations (e.g., a pier fill operation, a pier gap fill operation) that support forming piers in accordance with examples as disclosed herein. For example, the first set of manufacturing operations may include forming a set of piers 405 through the stack of layers by depositing one or more materials (e.g., one or more third materials), such as dielectric material (e.g., a second dielectric material) or a semiconductor (e.g., polysilicon), among other materials, in the cavities (e.g., filling the cavities). In some examples, the material of the piers 405 may be an oxide (e.g., a pier oxide), which may be the same as or similar to the dielectric material 435. In some examples, the material of the piers 405 may be chosen for having relatively high strength, high stiffness, or bonding strength with the dielectric material 435. In some examples, the first set of manufacturing operations may include a polishing or planarization operation to flatten a top surface of the layout 400, which may support aspects of subsequent operations.

In some cases, the first set of manufacturing operations may include removing (e.g., etching) portions of the stack of layers to form a set of cavities in the memory region along the z-direction. For example, the first set of manufacturing operations may include removing portions of the first material between layers of the dielectric material 435 to form the set of cavities (e.g., portions of the first material at levels 230). Forming the set of cavities may define a set of interleaved comb structures that enables the formation of word line structures, such as word lines 412 (e.g., word lines 205). For example, one or more conductive materials may be deposited in the set of cavities to form word lines, such as word lines 412-a and 412-b, which may be examples of a word line 205 (e.g., portions of a word line 205).

The first set of manufacturing operations may include further operations (e.g., a bottom electrode deposition) that support forming electrodes 410, which may be electrodes 410 between memory cells 105 and a respective word line 412. For example, manufacturing operations may include depositing an electrode material in contact with the material of the piers 405 and the dielectric material 435 to form the electrodes 410. The electrode material may be an example of a conductive material (e.g., tin nitride, tantalum nitride, or the like), and may enable the flow of current between a storage component of the memory cell and associated access circuitry (e.g., a word line 412, a pillar 220). For example, a memory cell may be coupled with the associated access circuitry via the electrodes 410. In some examples, the electrode material may be a metal or a carbide. The first set of manufacturing operations may include further operations (e.g., a bottom electrode recess etch operation) that support forming the electrodes. For example, the manufacturing operations may include removing (e.g., etching) exposed portions the electrode material, which may recess portions of the electrode material. For example, two portions of electrode material may remain, as shown by 410-a and 410-c.

The first set of manufacturing operations may also include operations that support forming memory cells 105. For example, the first set of manufacturing operations may include depositing a placeholder or sacrificial material 430 (e.g., a dielectric material, such as silicon nitride, among others) in contact with exposed portions of the electrode material of electrodes 410 and the material of the piers 405. In some examples, portions of the sacrificial material 430 may be removed from the memory region and replaced with a memory material, such as a chalcogenide material, in later operations. The manufacturing operations may include removing (e.g., etching) exposed portions the sacrificial material 430, which may recess portions of the sacrificial material 430. For example, two portions of the sacrificial material 430 may remain, as partially shown by 430-a and 430-b.

The first set of manufacturing operations may include operations (e.g., a gapfill operation) that support forming pillars (e.g., pillars 220) in the set of cavities. For example, the manufacturing operations may include depositing a third portion of the electrode material (e.g., electrode 410-b), a ceramic material 415, and a metallic material 420 in a cavity to form a pillar. In some examples, the electrode material may be etched after its deposition and prior to deposition of the ceramic material 415 and the metallic material 420 to expose the substrate 401 (e.g., or materials or components between the stack of layers and the substrate 401) such that the ceramic material 415 and the metallic material 420 in the cavities may be in contact with the substrate 401 (e.g., the materials or components between the stack of layers and the substrate 401). In some examples, the ceramic material 415 may be an example of titanium nitride (TiN), and may act as a barrier between the metallic material 420 and the other materials. In some examples, the metallic material 420 may be an example of conductive material, such as tungsten (W), and may form the conductive portion of the pillars (e.g., the pillars 220).

The first set of manufacturing operations may include forming a cavity 425 by removing a portion of the sacrificial material 430, leaving portions of the sacrificial material 430 (e.g., sacrificial material 430-a and 430-b). Accordingly, after the first set of manufacturing operations, the portion 400-a of the layout 400 may include sacrificial material 430-a between electrodes 410-a and 410-b and sacrificial material 430-b between electrodes 410-b and 410-c, as illustrated by the top view of the portion 400-a of the layout 400. Furthermore, each of the portions of sacrificial material 430-a and 430-b may be located between a first layer of the dielectric material 435-a and a second layer of the dielectric material 435-b, as illustrated by section A-A. Additionally, each of the electrodes 410-a, 410-b, and 410-c may be located between the first layer of the dielectric material 435-a and the second layer of the dielectric material 435-b, as illustrated by section B-B.

FIG. 4B illustrates a portion 400-b of the layout 400 after a second set of one or more manufacturing operations that supports memory cell protective layers in a three-dimensional memory array in accordance with examples as disclosed herein. The second set of manufacturing operations may include further operations (e.g., barrier formation operations) that support forming protective barriers that reduce or eliminate material diffusion between a memory cell and the dielectric materials 435. The second set of manufacturing operations may be performed after the first set of manufacturing operation, or may be a continuation of the first set of manufacturing operations.

The second set of manufacturing operations may include forming a barrier material 440 in the cavity 425 on one or more exposed surfaces of material. The barrier material 440 may include boron (e.g., and may be referred to as a boron-based material) as the inclusion of boron in the barrier material 440 may support the formation of thin barriers between memory cells and dielectric materials 435 while also supporting the electrical coupling of memory cells with associated access circuitry via the electrodes 410 even if a portion of the barrier material 440 is formed on surfaces of the electrodes 410). In some cases, the manufacturing operations may include performing a plasma procedure (e.g., chemical vapor deposition (CVD), plasma enhanced CVD (PECVD), or the like) in the cavity 425. For example, the manufacturing operations may include depositing a material including boron (e.g., boron halides, non-halides, trihalides, or other forms, including B₂H₆, B₂H₂(CH₃)₄, BBr₃, BF₃, BCl₃, borazine, among other materials including boron) in the cavity 425 on surfaces of the layers of dielectric materials 435-a and 435-b. The material including boron may also be deposited on surfaces of the electrodes 410 (e.g., and on a surface of the sacrificial material 430). The plasma procedure may cause nitrogen to bond with the material including boron to form the barrier material 440. For example, as part of the plasma procedure (e.g., a remote plasma procedure), nitrogen radicals may be formed in the cavity 425 (e.g., on the surfaces of the layers of dielectric materials 435-a and 435-b) which may bond with the material including boron such that the barrier material 440 is formed. In some examples, the barrier material 440 may include boron nitride, silicon boron nitride, or other materials (e.g., BGeN, BHfN, BAlN, BZrN, or BTiN being examples of materials including boron and transition metals, for example, where gases exist for atomic layer deposition (ALD) of such materials). In some examples, the manufacturing operations may include multiple cycles of forming the material including boron in the cavity 425 and performing the plasma procedure in the cavity 425 to form the barrier material 440 (e.g., to form a thicker layer of the barrier material 440).

In some examples, the formation of the material including boron in the cavity may include forming a vapor. For example, a vapor including boron (e.g., a boron source gas) may be formed (e.g., introduced, injected) in the cavity 425. In some examples, the vapor may be formed (e.g., adhered, adsorbed) on the surface of the layer of dielectric material 435-a and on the surface of layer of the dielectric material 435-b. Although the vapor (e.g., the material including boron) is formed on the bottom surface of the dielectric material 435-a and on the top surface of the dielectric material 435-b in the illustrative example of the portion 400-b of the layout 400, the vapor may also be formed on the top surface of dielectric material 435-a, on the bottom surface of the dielectric material 435-b, and on the top or bottom of one or more other layers of the dielectric material 435 in association with the formation of memory cells included in other levels of the memory device. In some cases, the vapor may also be formed on a surface of the electrode 410-a, one or more surfaces of the electrode 410-b, and a surface of the electrode 410-c.

In some cases, the plasma procedure may excite the vapor material with a plasma. For example, the plasma procedure may be a remote plasma procedure in which some materials of a plasma (e.g., hydrogen, helium, argon) are filtered (e.g., kept from being exposed to surfaces within the cavity 425) while other materials of the plasma (e.g., nitrogen, such as nitrogen radicals) may be applied to the surfaces within the cavity 425. The plasma may excite (e.g., surface heat, react with) the vapor such that the nitrogen radicals are bonded with the vapor to form the barrier material 440 including boron on the respective surfaces. In some examples, the barrier material 440 may be formed on the surface of the layer of dielectric material 435-a in the cavity 425 and on the surface of layer of the dielectric material 435-b in the cavity 425 (e.g., where the vapor was formed on the dielectric layers). Although the barrier material 440 is formed on the bottom surface of the dielectric material 435-a and on the top surface of the dielectric material 435-b in the illustrative example of the portion 400-b of the layout 400, the barrier material 440 may also be formed on the top surface of dielectric material 435-a, on the bottom surface of the dielectric material 435-b, and on the top or bottom of one or more other layers of the dielectric material 435 in association with the formation of memory cells included in other levels of the memory device. In some examples, the plasma procedure may be performed concurrent with forming the material including boron (e.g., the vapor including boron). Additionally, the plasma procedure and vapor formation may occur cyclically.

In some cases, the barrier material 440 may also be formed on all or a part of the surface of the electrodes 410-a and 410-b in the cavity 425 (e.g., where the vapor was formed on the electrodes 410), as illustrated by section B-B of the portion 400-b of the layout 400. For example, the barrier material 440 may be an electrically compatible material with the electrodes 410 (e.g., have a compatible bandgap), such that the electrodes 410 may interact with a memory cell 105 without (e.g., with minimal or non-substantial) interference from the barrier material 440. That is, the barrier material 440 may enable the coupling of a memory cell 105 and associated access circuitry via the electrodes 410 (e.g., even if being located between and physically separating the memory cell and the electrodes 410).

In some examples, the portions of the barrier material 440 formed on the electrodes 410 may thinner than the portions of the of barrier material 440 formed on the dielectric materials 435. For example, the layer of barrier material 440 formed on the dielectric materials 435 may be thick enough to prevent or reduce diffusion between the dielectric materials 435 and a memory cell 105 while the layer of barrier material 440 formed on the electrodes 410 may be thin enough to support electrical coupling between each of the electrodes 410 and a memory cell, as described with reference to FIG. 4C. In some examples, a thickness of the barrier material 440 formed on the electrodes 410 (e.g., a length of the barrier material 440 in the y-direction on the electrodes 410) may be in the angstrom range (e.g., as little as 5 to 25 angstroms). In some examples, the thickness of the barrier material 440 formed on the dielectric materials 435 may be in the angstrom range. In some examples, the thickness of the barrier material 440 formed on the dielectric materials may be in the nanometer range (e.g., between 1 to 15 nanometers, among other range of nanometers).

In some examples, the thickness of the barrier material 440 formed on the dielectric materials 435 relative to the electrodes 410 may be due to differences in material properties of the dielectric materials 435 and the electrodes 410. For example, a greater quantity of the material including boron formed in the cavity 425 may adhere to the surfaces of the dielectric materials 435 compared to a quantity of the material including boron that adheres to the surfaces of the electrodes 410. As a result, a greater quantity of, and thus thicker layer of, barrier material 440 may be formed on the dielectric materials 435 than the electrodes 410.

In some examples, the barrier material 440 may similarly be formed on a surface of the sacrificial material 430.

In some examples, a growth process may be performed in addition to the plasma procedure. For example, after the barrier material 440 is formed in the cavity 425, a second material (e.g., silicon radicals) may be applied to (e.g., formed on) the surface of the barrier material 440, and a second plasma procedure may excite the second material (e.g., a second vapor material) with a plasma. The second material may bond with the nitrogen radicals of the plasma, forming a barrier material 445 (e.g., silicon nitride) over the barrier material 440 (e.g., a dual barrier).

In some cases, the plasma procedure, the growth process, or both may be combined with one or more etching procedures. For example, alternative to a thin layer of the barrier material 440 on the electrodes 410, the etching procedure may remove a portion of the barrier material 440 from the surfaces of the electrodes 410 while maintaining the barrier material 440 on the surfaces of the dielectric materials 435.

FIG. 4C illustrates a portion 400-c of the layout 400 after a third set of one or more manufacturing operations that supports memory cell protective layers in a three-dimensional memory array in accordance with examples as disclosed herein. The third set of manufacturing operations may include further operations (e.g., memory cell formation operations) that support forming a memory cell 450 (e.g., a memory cell 105) that is protected by the barrier material 440. The third set of manufacturing operations may be performed after the second set of manufacturing operation, or may be a continuation of the second set of manufacturing operations.

The third set of one or more manufacturing operations may support forming the memory cells 105. For example, the manufacturing operations may include depositing a storage material in the of cavity 425 (e.g., a remaining portion of the cavity 425 after formation of the barrier material 440), as described with reference to FIGS. 4A and 4B. In some cases, the storage material may be a material configured to store a logic state of a memory cell, such as a chalcogenide glass or a chalcogenide alloy. Accordingly, after being deposited, the storage material may be in contact with the barrier material 440, one or more electrodes 410, or both. Alternatively, if the cavity has a dual barrier, the storage material may be in contact with the barrier material 445, one or more electrodes 410, or both. The manufacturing operations may also include a recess or etch of the storage material to form a memory cell 450 in the cavity 425, such that the protected memory cell 450 is located between the barrier material 440, 445, or both, over the layers of dielectric materials 435 and between the barrier material 440, 445, or both, over the electrodes 410. That is, the barrier material 440 (e.g., and the barrier material 445) may be located between the memory cell 450 and the dielectric materials 435. In some examples, the barrier material 440 (e.g., and the barrier material 445) may also be located between the memory cell 450 and the electrodes 410. In some examples, the barrier material 440 (e.g., and the barrier material 445) may also be located between the memory cell 450 and the sacrificial material 430. In some cases, the memory cell 450 may couple with the pillar materials (e.g., 415 and 420) via the electrode 410-b and the word line 412-a (e.g., a word line member of a word line 205) via the electrode 410-a.

The manufacturing operations may also include depositing a sealing material 455, which may be an example of a dielectric material, in the of cavity 425. For example, the manufacturing operations may perform an ALD in the cavity 425. In some cases, the sealing material may be deposited in contact with each memory cell 450 of each cavity 425. The sealing material 455, along with a gap fill material, may form a set of respective dielectric portions. In some cases, forming the set of dielectric portions may further include performing a polishing or a planarization process to smooth or polish the top of the portion 400-c of the layout 400.

The barrier material 440 may isolate the memory cell 450 from the layers of dielectric materials 435-a and 435-b. For example, the barrier material 440 may physically separate the memory cell 450 from the layers of the dielectric materials 435 which may prevent or reducing diffusion between the memory cell 450 and layers of dielectric materials 435-a and 435-b, such as diffusion of low binary bond activation energy element combinations (e.g., oxygen diffusion into the memory cell 450, diffusion out of the memory cell 450 of, for example, In—Se, As—Se, In—In, In—Sb, In—Te, In—S, Se—Se, As—H, Se—H, among other element combinations), while supporting access to the memory cell via the electrodes 410-a and 410-b.

FIG. 5 illustrates the layout 500 after a fourth set of one or more manufacturing operations that supports memory cell protective layers in a three-dimensional memory array in accordance with examples as disclosed herein. The fourth set of manufacturing operations may include further operations (e.g., barrier formation operations) that support forming the protective barriers between a memory cell 550 and dielectric materials 535. In some cases, the fourth set of manufacturing operations may be an alternative to the second set of manufacturing operations and before the third set of manufacturing operations, as described with reference to FIGS. 4B and 4C. Alternatively, the fourth set of manufacturing operations may be performed after the first set of manufacturing operations and before the second set of manufacturing operations and the third set of manufacturing operations, and therefore may support forming an additional barrier (e.g., in addition to the barrier material 440).

For instance, before a memory cell 550 is formed, the fourth set of manufacturing operations may include performing a doping procedure (e.g., boron-doping), of dielectric materials 535-a and 535-b, electrodes 510 (e.g., electrodes 510-a. 510-b, 510-c), or both, formed over a substrate 501, which may be examples of the dielectric materials 435, the electrodes 410, and the substrate 401 described with reference to FIGS. 4A through 4C. For example, a material 560 that includes boron (e.g., boron halides, non-halides, trihalides, or other forms, including B₂H₆, B₂H₂(CH₃)₄, BBr₃, BF₃, BCl₃, borazine, among other materials including boron) may be deposited on to the layers of dielectric materials 535, the electrodes 510, or a combination thereof (e.g., the material may be formed in a cavity 425). In some examples, the doping procedure may bond the material 560 with oxygen and/or silicon included in the layers of dielectric material 535, which may later prevent or reduce the diffusion of oxygen into the memory cell 550. For example, due to the oxygen bonding with the material 560, the oxygen may be unable to bond with materials of the memory cell 550.

The material 560 may be diffused into the respective areas of deposition, including the layer of dielectric material 535-a, the layer of dielectric material 535-b, the electrodes 510, or a combination thereof. In some cases, the diffusion may be performed thermally. In some cases, the diffusion may be performed through an exposure procedure or a growth procedure (e.g., CVD). For example, the material 560 may be formed on the surfaces of the dielectric materials 535, the electrodes 510, or a combination thereof, and a rapid thermal annealing procedure, a laser treatment, a microwave treatment, or a combination thereof, may be performed to diffuse the material 560 into the surfaces. The diffusion of the material 560 may be relatively localized to the surfaces of the dielectric materials 535, the electrodes 510, or both. In some examples, the doping procedure may also include the doping of a sacrificial material 530, which may be an example of a sacrificial material 430. The sacrificial material 530 may be in contact with a pier 505, which may be an example of a pier 405.

In some cases, the fourth set of manufacturing operations may include a second procedure to apply nitrogen to the diffused material 560 (e.g., nitridizing the material 560). For example, nitrogen may be deposited in the cavity 425, as described with reference to FIGS. 4A-4B, through a plasma procedure. A plasma may excite (e.g., surface heat, react with) the material 560 such that nitrogen radicals are bonded with the material 560 to form a barrier material 540 including boron (e.g., boron nitride, or silicon boron nitride, or other materials including boron and transition metals) on the respective surfaces. In some cases, the plasma procedure may form the barrier material 540 from all of the diffused material 560. Alternatively, a first portion of the diffused material 560 may remain and the plasma procedure may form the barrier material 540 from a second portion of the diffused material 560.

In some examples, the barrier material 540 may be formed on (e.g., over) the surface of the layer of dielectric material 535-a in a cavity (e.g., a cavity 425) and on the surface of layer of the dielectric material 535-b in the cavity (e.g., where the material 560 was diffused into the dielectric layers). Although the barrier material 540 is formed on the bottom surface of the dielectric material 535-a and on the top surface of the dielectric material 535-b in the illustrative example of layout 500, the barrier material 540 may also be formed on the top surface of dielectric material 535-a, on the bottom surface of the dielectric material 535-b, and on the top or bottom of one or more other layers of the dielectric material 535. In some examples, the plasma procedure may occur cyclically.

In some examples, a barrier material 440 (e.g., and a barrier material 445) as described with reference to FIGS. 4B and 4C may be formed over the surfaces of the dielectric materials 535 doped with the material 560 (e.g., over the barrier material 540).

The third set of manufacturing operations, described with reference to FIG. 4C, may occur after the fourth set of one or more manufacturing operations. For example, after the material 560 is diffused and nitridized, or alternatively, after the barrier material 540 is formed, the manufacturing operations may include depositing a storage material in the of cavity 425, as described with reference to FIGS. 4A and 4B. Accordingly, after being deposited, the storage material may be in contact with the layers of boron-doped dielectric material 535 (e.g., dielectric material 535 doped with the material 560), one or more electrodes 510, or both. Alternatively, if the cavity has a barrier material 540, the storage material may be in contact with the barrier material 540, one or more of the electrodes 510, or both. The manufacturing operations may also include a recess or etch of the storage material to form a memory cell 550 in the cavity, such that the protected memory cell 550 is located between the barrier material 540 over the layers of dielectric materials 535 and between the barrier material 540 over the electrodes 510, or alternatively, between the boron-doped layers of dielectric materials 535 and between the electrodes 510 (e.g., boron-doped electrodes 510). In some cases, the memory cell 550 may couple with the pillar materials (e.g., pillar materials 515 and 520) via electrode 510-b and a word line 512 (e.g., a word line 412) via electrode 510-a.

The manufacturing operations may also include depositing a sealing material 555, which may be an example of a dielectric material, in the of cavity. For example, the manufacturing operations may perform an ALD in the cavity. In some cases, the sealing material may be deposited in contact with each memory cell 550 of each cavity. The sealing material 555, along with a gap fill material, may form a set of respective dielectric portions. In some cases, forming the set of dielectric portions may further include performing a polishing or a planarization process to smooth or polish the top of the layout 500.

In some cases, the boron-doped layers of dielectric materials 535-a and 535-b may prevent or reducing diffusion (oxygen in-diffusion) to the memory cell 550, due to the material 560 bonding with the oxygen of the dielectric materials 535-a and 535-b. Additionally, or alternatively, the barrier material 540 may isolate the memory cell 550 from the layers of dielectric materials 535-a and 535-b. For example, the barrier material 540 may prevent or reducing diffusion between the memory cell 550 and layers of dielectric materials 535-a and 535-b, such as diffusion of low binary bond activation energy element combinations (e.g., low diatomic bond strength elements), while supporting access to the memory cell via the electrodes 510-a and 510-b.

FIG. 6 illustrates a flowchart showing a method 600 that supports memory cell protective layers in a three-dimensional memory array in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming a stack of layers over a substrate, the stack of layers including layers of a first material and layers of a dielectric material. The operations of 605 may be performed in accordance with examples as disclosed herein.

At 610, the method may include removing a portion of a layer of the first material, where a cavity between a first layer of the dielectric material and a second layer of the dielectric material is formed based at least in part on the removing. The operations of 610 may be performed in accordance with examples as disclosed herein.

At 615, the method may include forming a barrier material including boron in the cavity, where the barrier material is formed on a first surface of the first layer of the dielectric material and on a second surface of the second layer of the dielectric material. The operations of 615 may be performed in accordance with examples as disclosed herein.

At 620, the method may include forming a memory cell between the barrier material on the first surface of the first layer of the dielectric material and the barrier material on the second surface of the second layer of the dielectric material, where the memory cell is isolated from the dielectric material based at least in part on the barrier material. The operations of 620 may be performed in accordance with examples as disclosed herein.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a stack of layers over a substrate, the stack of layers including layers of a first material and layers of a dielectric material; removing a portion of a layer of the first material, where a cavity between a first layer of the dielectric material and a second layer of the dielectric material is formed based at least in part on the removing; forming a barrier material including boron in the cavity, where the barrier material is formed on a first surface of the first layer of the dielectric material and on a second surface of the second layer of the dielectric material; and forming a memory cell between the barrier material on the first surface of the first layer of the dielectric material and the barrier material on the second surface of the second layer of the dielectric material, where the memory cell is isolated from the dielectric material based at least in part on the barrier material.
Aspect 2: The method or apparatus of aspect 1, where forming the barrier material includes operations, features, circuitry, logic, means, or instructions, or any combination thereof for depositing a second material including boron in the cavity on the first surface and the second surface and performing a plasma procedure in the cavity.
Aspect 3: The method or apparatus of aspect 2, where depositing the second material is concurrent with performing the plasma procedure.
Aspect 4: The method or apparatus of any of aspects 2 through 3, where performing the plasma procedure includes operations, features, circuitry, logic, means, or instructions, or any combination thereof for bonding nitrogen associated with the plasma procedure with the second material to form the barrier material.
Aspect 5: The method or apparatus of any of aspects 1 through 4, where forming the barrier material includes operations, features, circuitry, logic, means, or instructions, or any combination thereof for forming a vapor including boron in the cavity and exciting the vapor with a plasma, where the plasma reacts with the vapor to form the barrier material based at least in part on the exciting.
Aspect 6: The method or apparatus of any of aspects 1 through 5, further including operations, features, circuitry, logic, means, or instructions, or any combination thereof for forming a first electrode and a second electrode based at least in part on removing the layer of the first material; where forming the barrier material includes forming the barrier material on a third surface of the first electrode and on a fourth surface of the second electrode; and where forming the memory cell includes forming the memory cell between the barrier material on the third surface of the first electrode and the barrier material on the fourth surface of the second electrode.
Aspect 7: The method or apparatus of aspect 6, where a first thickness of the barrier material on the first surface of the first layer of the dielectric material or on the second surface of the second layer of the dielectric material is greater than a second thickness of the barrier material on the third surface of the first electrode and on the fourth surface of the second electrode.
Aspect 8: The method or apparatus of aspect 7, where the first electrode couples the memory cell with a word line and the second electrode couples the memory cell with a pillar associated with accessing the memory cell based at least in part on the second thickness of the barrier material
Aspect 9: The method or apparatus of any of aspects 1 through 8, further including operations, features, circuitry, logic, means, or instructions, or any combination thereof for forming a second barrier material on the barrier material of the first surface of the first layer of the dielectric material and on the barrier material of the second surface of the second layer of the dielectric material, where the second barrier material includes silicon nitride and forming the memory cell between the second barrier material on the first surface of the first layer of the dielectric material and the second barrier material on the second surface of the second layer of the dielectric material, where the memory cell is isolated from the dielectric material based at least in part on the barrier material and the second barrier material.
Aspect 10: The method or apparatus of any of aspects 1 through 9, where the barrier material includes boron nitride.
Aspect 11: The method or apparatus of any of aspects 1 through 10, where each of the layers of the first material are separated from each other by a respective layer of the dielectric material.

FIG. 7 illustrates a flowchart showing a method 700 that supports memory cell protective layers in a three-dimensional memory array in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include forming a stack of layers over a substrate, the stack of layers including layers of a first material and a dielectric material. The operations of 705 may be performed in accordance with examples as disclosed herein.

At 710, the method may include removing a portion of a layer of the first material, where a cavity between a first layer of the dielectric material and a second layer of the dielectric material is formed based at least in part on the removing. The operations of 710 may be performed in accordance with examples as disclosed herein.

At 715, the method may include doping both a first surface of the first layer of the dielectric material and a second surface of the second layer of the dielectric material with a second material including boron. The operations of 715 may be performed in accordance with examples as disclosed herein.

At 720, the method may include forming a memory cell between the doped first surface of the first layer of the dielectric material and the doped second surface of the second layer of the dielectric material. The operations of 720 may be performed in accordance with examples as disclosed herein.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 12: A method or apparatus including operations, features, circuitry, logic, means, or instructions, or any combination thereof for forming a stack of layers over a substrate, the stack of layers including layers of a first material and a dielectric material; removing a portion of a layer of the first material, where a cavity between a first layer of the dielectric material and a second layer of the dielectric material is formed based at least in part on the removing; doping both a first surface of the first layer of the dielectric material and a second surface of the second layer of the dielectric material with a second material including boron; and forming a memory cell between the doped first surface of the first layer of the dielectric material and the doped second surface of the second layer of the dielectric material.
Aspect 13: The method or apparatus of aspect 12, where doping the first surface of the first layer of the dielectric material and the second surface of the second layer of the dielectric material with the second material includes operations, features, circuitry, logic, means, or instructions, or any combination thereof for depositing the second material onto the first surface of the first layer of the dielectric material and the second surface of the second layer of the dielectric material and diffusing the second material into the first surface of the first layer of the dielectric material and the second surface of the second layer of the dielectric material.
Aspect 14: The method or apparatus of aspect 13, where diffusing the second material includes performing a rapid thermal annealing procedure, a laser treatment, a microwave treatment, or any combination thereof.
Aspect 15: The method or apparatus of any of aspects 12 through 14, further including operations, features, circuitry, logic, means, or instructions, or any combination thereof for forming a barrier material including boron over the doped first surface of the first layer of the dielectric material and over the doped second surface of the second layer of the dielectric material, where the memory cell is isolated from the dielectric material based at least in part on the barrier material.
Aspect 16: The method or apparatus of aspect 15, where forming the barrier material includes operations, features, circuitry, logic, means, or instructions, or any combination thereof for performing a plasma procedure in the cavity, where nitrogen associated with the plasma procedure is bonded with the second material to form the barrier material based at least in part on the doping and performing the plasma procedure.
Aspect 17: The method or apparatus of any of aspects 15 through 16, where the barrier material includes boron nitride, or silicon boron nitride, germanium, aluminum, one or more doped-transition metals, or any combination thereof.
Aspect 18: The method or apparatus of any of aspects 12 through 17, further including operations, features, circuitry, logic, means, or instructions, or any combination thereof for forming a first electrode and a second electrode based at least in part on removing the layer of the first material; doping a third surface of the first electrode and a fourth surface of the second electrode with the second material; and where forming the memory cell includes forming the memory cell between the third surface of the first electrode and the fourth surface of the second electrode.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 19: An apparatus, including: a plurality of levels of a memory array arranged over a substrate and separated from each other by a respective layer of a plurality of layers of a dielectric material; a pillar extending through the plurality of levels of the memory array in a first direction, where, at each level of the plurality of levels, one or more memory cells of the memory array are coupled with a respective word line and the pillar; and a barrier material including boron and located between a respective memory cell and respective layers of the dielectric material in between which the respective memory cell is located, where the respective memory cell is isolated from the dielectric material based at least in part on the barrier material.
Aspect 20: The apparatus of aspect 19, where each of the respective layers of the dielectric material include a surface doped with a second material including boron.
Aspect 21: The apparatus of any of aspects 19 through 20, further including: a first electrode between the respective memory cell and the respective word line, and a second electrode between the respective memory cell and the pillar, where the barrier material is located between the respective memory cell and each of the first electrode and the second electrode in between which the respective memory cell is located.
Aspect 22: The apparatus of aspect 21, where a first thickness of the barrier material located between the respective memory cell and a respective layer of the dielectric material is greater than a second thickness of the barrier material located between the respective memory cell and the first electrode or the second electrode.
Aspect 23. The apparatus of any of aspects 19 through 22, further including: a second barrier material located between the respective memory cell and the barrier material, where the respective memory cell is isolated from the dielectric material based at least in part on the barrier material and the second barrier material.
Aspect 24: The apparatus of aspect 23, where the second barrier material includes silicon nitride.
Aspect 25: The apparatus of any of aspects 19 through 24, where the barrier material includes boron nitride, silicon boron nitride, germanium, aluminum, one or more doped-transition metals, or any combination thereof.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrodes), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration.” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
forming a stack of layers over a substrate, the stack of layers comprising layers of a first material and layers of a dielectric material;
removing a portion of a layer of the first material, wherein a cavity between a first layer of the dielectric material and a second layer of the dielectric material is formed based at least in part on the removing;
forming a barrier material comprising boron in the cavity, wherein the barrier material is formed on a first surface of the first layer of the dielectric material and on a second surface of the second layer of the dielectric material; and
forming a memory cell between the barrier material on the first surface of the first layer of the dielectric material and the barrier material on the second surface of the second layer of the dielectric material, wherein the memory cell is isolated from the dielectric material based at least in part on the barrier material.

2. The method of claim 1, wherein forming the barrier material comprises:
depositing a second material comprising boron in the cavity on the first surface and the second surface; and
performing a plasma procedure in the cavity.

3. The method of claim 2, wherein depositing the second material is concurrent with performing the plasma procedure.

4. The method of claim 2, wherein performing the plasma procedure comprises:
bonding nitrogen associated with the plasma procedure with the second material to form the barrier material.

5. The method of claim 1, wherein forming the barrier material comprises:
forming a vapor comprising boron in the cavity; and
exciting the vapor with a plasma, wherein the plasma reacts with the vapor to form the barrier material based at least in part on the exciting.

6. The method of claim 1, further comprising:
forming a first electrode and a second electrode based at least in part on removing the layer of the first material, wherein forming the barrier material comprises forming the barrier material on a third surface of the first electrode and on a fourth surface of the second electrode, and wherein forming the memory cell comprises forming the memory cell between the barrier material on the third surface of the first electrode and the barrier material on the fourth surface of the second electrode.

7. The method of claim 6, wherein a first thickness of the barrier material on the first surface of the first layer of the dielectric material or on the second surface of the second layer of the dielectric material is greater than a second thickness of the barrier material on the third surface of the first electrode and on the fourth surface of the second electrode.

8. The method of claim 1, further comprising:
forming a second barrier material on the barrier material of the first surface of the first layer of the dielectric material and on the barrier material of the second surface of the second layer of the dielectric material, wherein the second barrier material comprises silicon nitride; and
forming the memory cell between the second barrier material on the first surface of the first layer of the dielectric material and the second barrier material on the second surface of the second layer of the dielectric material, wherein the memory cell is isolated from the dielectric material based at least in part on the barrier material and the second barrier material.

9. A method, comprising:
forming a stack of layers over a substrate, the stack of layers comprising layers of a first material and a dielectric material;
removing a portion of a layer of the first material, wherein a cavity between a first layer of the dielectric material and a second layer of the dielectric material is formed based at least in part on the removing;
doping both a first surface of the first layer of the dielectric material and a second surface of the second layer of the dielectric material with a second material comprising boron; and
forming a memory cell between the doped first surface of the first layer of the dielectric material and the doped second surface of the second layer of the dielectric material.

10. The method of claim 9, wherein doping the first surface of the first layer of the dielectric material and the second surface of the second layer of the dielectric material with the second material comprises:
depositing the second material onto the first surface of the first layer of the dielectric material and the second surface of the second layer of the dielectric material; and
diffusing the second material into the first surface of the first layer of the dielectric material and the second surface of the second layer of the dielectric material.

11. The method of claim 10, wherein diffusing the second material comprises performing a rapid thermal annealing procedure, a laser treatment, a microwave treatment, or any combination thereof.

12. The method of claim 9, further comprising:
forming a barrier material comprising boron over the doped first surface of the first layer of the dielectric material and over the doped second surface of the second layer of the dielectric material, wherein the memory cell is isolated from the dielectric material based at least in part on the barrier material.

13. The method of claim 12, wherein the barrier material comprises boron nitride, or silicon boron nitride, germanium, aluminum, one or more doped-transition metals, or any combination thereof.

14. An apparatus, comprising:
a plurality of levels of a memory array arranged over a substrate and separated from each other by a respective layer of a plurality of layers of a dielectric material;
a pillar extending through the plurality of levels of the memory array in a first direction, wherein, at each level of the plurality of levels, one or more memory cells of the memory array are coupled with a respective word line and the pillar; and
a barrier material comprising boron and located between a respective memory cell and respective layers of the dielectric material in between which the respective memory cell is located, wherein the respective memory cell is isolated from the dielectric material based at least in part on the barrier material.

15. The apparatus of claim 14, wherein each of the respective layers of the dielectric material comprise a surface doped with a second material comprising boron.

16. The apparatus of claim 14, further comprising:
a first electrode between the respective memory cell and the respective word line; and
a second electrode between the respective memory cell and the pillar, wherein the barrier material is located between the respective memory cell and each of the first electrode and the second electrode in between which the respective memory cell is located.

17. The apparatus of claim 16, wherein a first thickness of the barrier material located between the respective memory cell and a respective layer of the dielectric material is greater than a second thickness of the barrier material located between the respective memory cell and the first electrode or the second electrode.

18. The apparatus of claim 14, further comprising:
a second barrier material located between the respective memory cell and the barrier material, wherein the respective memory cell is isolated from the dielectric material based at least in part on the barrier material and the second barrier material.

19. The apparatus of claim 18, wherein the second barrier material comprises silicon nitride.

20. The apparatus of claim 14, wherein the barrier material comprises boron nitride, silicon boron nitride, germanium, aluminum, one or more doped-transition metals, or any combination thereof.
